(19) United States
(12) Patent Application Publication
(10) Pub. No.: US 2023/0348780 A1
(43) Pub. Date: Nov. 2, 2023

(54) PHOSPHOR POWDER, COMPOSITE, LIGHT-EMITTING DEVICE, AND METHOD FOR PRODUCING PHOSPHOR POWDER

(71) Applicant: DENKA COMPANY LIMITED, Tokyo (JP)

(72) Inventors: Moeko TANAKA, Tokyo (JP); Tomohiro NOMIYAMA, Tokyo (JP); Marina TAKAMURA, Tokyo (JP)

(73) Assignee: DENKA COMPANY LIMITED, Tokyo (JP)

(21) Appl. No.: 17/914,263

(22) PCT Filed: Mar. 19, 2021
(86) PCT No.: PCT/JP2021/011488

§ 371 Date: Sep. 23, 2022

(30) Foreign Application Priority Data
Mar. 30, 2020 (JP) 2020-061212

(51) Int. Cl. C09K 11/64; C09K 11/59; C09K 11/08; C09K 11/02; H01L 33/50

(52) U.S. Cl. CPC C09K 11/64; C09K 11/59; C09K 11/0883; C09K 11/02; H01L 33/502

(57) ABSTRACT

A phosphor powder consists of a red phosphor represented by a general formula (Srₓ, Ca_{1-x-y}, Eu_{y})AlSi(N,O)₃ having the same crystal phase as that of CASN. In a general formula, a relationship of x<1 and 1−x−y>0 are satisfied. In addition, a peak wavelength of a fluorescence spectrum, in a case where the phosphor powder is irradiated with blue excitation light having a wavelength of 455 nm is equal to or more than 600 nm and equal to or less than 610 nm, and a full width at half maximum of the fluorescence spectrum is equal to or less than 73 nm.

### TECHNICAL FIELD

The present invention relates to a phosphor powder, a composite, a light-emitting device, and a method for producing the phosphor powder.

### BACKGROUND ART

In order to manufacture a white LED, a red phosphor that converts blue light from a blue LED chip into red light is being studied. As the red phosphor, so-called CASN, SCASN, and the like are known.

As a specific example, Patent Document 1 discloses a phosphor containing a crystal phase represented by a general formula, MₐSr_{b}Ca_{c}Al_{d}SiₑN_{f} and having a quantum efficiency maintenance rate of equal to or more than 85% at photoexcitation of 4000 mW/mm². In this general formula, M represents an active element, 0<a<0.05, 0.95≤b≤1, 0≤c<0.1, a+b+c=1, 0.7≤d≤1.3, 0.7≤e≤1.3, and 2.5≤f≤3.5.

### RELATED DOCUMENT

### Patent Document

[Patent Document 1] Japanese Unexamined Patent Publication No. 2019-077800

### SUMMARY OF THE INVENTION

### Technical Problem

So far, various improvements have been made to a red phosphor that converts blue light from a blue LED chip into red light. However, there is still room for improvement in terms of brightness when a white LED is used.

The present invention has been made in view of such circumstances.

One of objects of the present invention is to improve the brightness of the white LED by improving the red phosphor.

### Solution to Problem

The inventors of the present invention have completed the present invention provided below and solved the problem described above.

According to the present invention, there is provided
a phosphor powder consisting of a red phosphor represented by a general (Srₓ, Ca_{1-x-y}, Eu_{y})AlSi(N,O)₃ having the same crystal phase as that of CASN, relationships of x<1 and 1−x−y>0 are satisfied, a peak wavelength of a fluorescence spectrum in a case where blue excitation light at a wavelength of 455 nm is emitted is equal to or more than 600 nm and equal to or less than 610 nm, and a full width at half maximum of the fluorescence spectrum is equal to or less than 73 nm.

In addition, according to the present invention, there is provided
a composite including the phosphor powder, and a sealing material that seals the phosphor powder.

In addition, according to the present invention, there is provided
a light-emitting device including a light-emitting element that emits excitation light, and the composite that converts a wavelength of the excitation light.

In addition, according to the present invention, there is provided
a method for producing the phosphor powder, the method including a mixing step of mixing a starting raw material to form a raw material mixed powder, and a firing step of firing the raw material mixed powder to obtain a fired product, in which the starting raw material contains SCASN phosphor nucleus particles having an average particle diameter equal to or more than 5 μm and equal to or less than 30 μm.

### Advantageous Effects Of Invention

By using the red phosphor of the present invention, brightness of a white LED can be improved.

### BRIEF DESCRIPTION OF THE DRAWINGS

FIG. 1 is a schematic cross-sectional view showing an example of a structure of a light-emitting device.

### DESCRIPTION OF EMBODIMENTS

Hereinafter, an embodiment of the present invention will be described in detail while referring to drawings.

In the drawings, similar components are designated by the same reference numerals, and the description thereof will not be repeated.

In order to avoid complication, in a case where there are a plurality of the same components in the same drawing, only one of thereof may be denoted and not all thereof may be denoted in some cases.

The drawings are for explanation purposes only. A shape or a dimensional ratio of each member in the drawing does not necessarily correspond to an actual article.

In the present specification, unless particularly otherwise described explicitly, the term “substantially” indicates that production tolerances, assembly variations, and the like are included in ranges.

Strictly, “brightness” is a physical quantity (unit: cd/m²) defined by using light intensity of a light source and an angle facing a light source surface. However, the term “brightness” used in the present specification is used in a broader sense. The term “brightness” in the present specification has meanings of a “degree of brightness of light felt by human” or a “sensory light intensity in consideration of visual sensitivity of human eyes”.

### Phosphor Powder

The phosphor powder of the present embodiment consists of a red phosphor represented by a general formula (Srₓ, Ca_{1-x-y}, Eu_{y})AlSi(N,O)₃ having the same crystal phase as that of CASN. In this general formula, a relationship of x<1 and 1−x−y>0 are satisfied.

In addition, a peak wavelength of a fluorescence spectrum, in a case where the phosphor powder of the present embodiment is irradiated with blue excitation light having a wavelength of 455 nm is equal to or more than 600 nm and equal to or less than 610 nm, and preferably equal to or more than 602 nm and equal to or less than 609 nm. Further, a full width at half maximum of this fluorescence spectrum is equal to or less than 73 nm, preferably equal to or more than 70 nm and equal to or less than 73 nm, and more preferably equal to or more than 71 nm and equal to or less than 73 nm.

In order to improve the brightness of the white LED by improving the red phosphor, it is conceivable to simply increase a peak intensity of a light emission spectrum of the red phosphor.

Meanwhile, in a case of red light, the brightness can be improved by shortening a peak “wavelength” of the light emission (fluorescence) spectrum due to a relationship of visual sensitivity. That is, in a wavelength region of red light, humans tend to feel “brighter” in light having a short wavelength than in light having a long wavelength. In the present embodiment, based on this, a phosphor is designed so that a peak wavelength of a fluorescence spectrum, in a case where blue excitation light at a wavelength of 455 nm is emitted, is equal to or more than 600 nm and equal to or less than 610 nm, in the red phosphor represented by the general formula (Srₓ, Ca_{1-x-y}, Eu_{y})AlSi(N, O)₃ having the same crystal phase as that of CASN. By this “shortening of the peak wavelength”, the brightness of the white LED can be improved.

In addition, according to the findings of the inventors of the present invention, in the related art, in a case where the peak wavelength of the red phosphor is designed to be shortened, the peak intensity may decrease, but in the present embodiment, the red phosphor is designed so that the full width at half maximum of the fluorescence spectrum is equal to or less than 73 nm, thereby increasing the peak intensity of the fluorescence spectrum (not making that the peak top low).

The phosphor particles of the present embodiment, in which the peak wavelength of the fluorescence spectrum is a short wavelength and the full width at half maximum of the fluorescence spectrum is small, are preferably used for improving the brightness of the white LED.

The phosphor powder of the present embodiment can be obtained by appropriately selecting raw materials, and selecting a usage ratio of each raw material, a producing procedure, producing conditions, and the like. The selection of raw materials and an amount ratio of raw materials preferably include usage of a large amount of a Sr-containing raw material, usage of a small amount of an Eu-containing raw material, addition of “nucleus” which will be described later, and the like. The producing procedure and producing conditions preferably include performing of firing using a container made of a high melting metal, for example, a container made of tungsten, molybdenum, or tantalum, and the like. These details will be described later.

The description of the phosphor powder of the present embodiment will be continued.

### Crystal Structure, Elemental Composition, and the Like

The phosphor particles of the present embodiment consist of a red phosphor represented by a general formula (Srₓ, Ca_{1-x-y}, Eu_{y})AlSi(N,O)₃ having the same crystal phase as that of CASN (that is, CaAlSiN₃). In this general formula, a relationship of x<1 and 1−x−y>0 are satisfied. Here, (N,O) means that a part of N is unavoidably replaced with O.

The crystal phase can be confirmed by powder X-ray diffraction. The crystal phase is preferably a single phase of a crystal, but may contain a heterogeneous phase as long as it does not significantly affect the properties of the phosphor. The presence or absence of the heterogeneous phase can be determined, for example, by powder X-ray diffraction based on the presence or absence of a peak other than that due to the target crystal phase.

A skeleton structure of CASN is configured with (Si,Al)-N₄ regular tetrahedrons bonded to each other, and Ca atoms are located in a gap of the skeleton. Apart of Ca²⁺ is replaced with Eu²⁺, which acts as a light emission center, to form a red phosphor.

With respect to x, it is preferably 0.9<x<1, more preferably 0.92<x<1, and even more preferably 0.95<x<1. As the findings of the inventors of the present invention, in a case where the Sr amount in the phosphor particles of the present embodiment is large, the peak wavelength or the full width at half maximum of the fluorescence spectrum are likely to be in the numerical ranges described above.

As another index from a viewpoint of “the large Sr amount”, a molar ratio of Sr/(S+Ca) is preferably equal to or more than 0.96 and equal to or less than 0.999 and more preferably equal to or more than 0.97 and equal to or less than 0.999.

With respect to y, it is preferably y<0.01, more preferably 0.0005<y<0.005, and even more preferably 0.001<y<0.005.

Generally, from a viewpoint of peak intensity, it is preferable that the phosphor particles contain a large amount of Eu to some extent, but from a viewpoint of shortening the wavelength, it is preferable that the amount of Eu is relatively small in the present embodiment.

### Median Diameter

A median diameter of the phosphor particles of the present embodiment is preferably equal to or more than 1 μm and equal to or less than 40 μm and more preferably equal to or more than 10 μm and equal to or less than 30 μm. For the purpose of converting blue light from a blue LED into red light, this median diameter is preferable from a viewpoint of balance of various performances such as brightness or conversion efficiency.

The median diameter can be measured as a volume-based value by a laser diffraction scattering method.

The median diameter can be adjusted by appropriately applying well-known means such as pulverization and sieving. The details thereof will be described later.

### Method for Producing Phosphor Powder

The phosphor powder of the present embodiment can be obtained by appropriately selecting raw materials, and selecting a usage ratio of each raw material, a producing procedure, producing conditions, and the like. Specifically, the phosphor powder of the present embodiment is preferably produced through the following steps.
Mixing step of mixing a starting raw material to form a raw material mixed powder
Firing step of firing the raw material mixed powder to obtain a fired product

In addition, in the production of the phosphor powder, there may be additional steps other than these steps.

Hereinafter, the mixing step, the firing step, and additional steps other than these steps will be described.

### Mixing Step

In the mixing step, the starting raw materials are mixed to form a raw material mixed powder.

Examples of the starting raw material include a europium compound, a strontium compound such as strontium nitride, a calcium compound such as calcium nitride, silicon nitride, and aluminum nitride.

The form of each starting raw material is preferably powder state.

Examples of europium compound include an oxide containing europium, a hydroxide containing europium, a nitride containing europium, an oxynitride containing europium, and a halide containing europium. These can be used alone or in combination of two or more.

Among them, europium oxide, europium nitride and europium fluoride are preferably used alone, and europium oxide is more preferably used alone.

In the firing step, europium is divided into those that are doped, those that volatilize, and those that remain as a heterogeneous phase component. The heterogeneous phase component containing europium can be removed by an acid treatment or the like. However, in a case where a significantly large amount thereof is generated, a component insoluble by the acid treatment may be generated and the brightness may decrease. In addition, as long as it is a heterogeneous phase that does not absorb excess light, it may be in a residual state, and europium may be contained in this heterogeneous phase.

The amount of the europium compound used is not limited, but assuming that a charging ratio is directly reflected in a final composition ratio, y in the general formula described above is preferably used in an amount of y<0.01, more preferably 0.0005<y<0.005, and even more preferably 0.001<y<0.005. In addition, in a case of using the nuclear particles which will be described later, the y in the inequations does not contain the amount of europium in the nuclear particles.

From a viewpoint of shortening the wavelength, it is preferable that the amount of europium is relatively small in the present embodiment.

Meanwhile, regarding the amount of the strontium compound, assuming that the charging ratio is directly reflected in the final composition ratio, x in the general formula described above is preferably used in amount of 0.9≤x<1, more preferably 0.92≤x<1, and more preferably 0.95≤x<1. In addition, in a case of using the nuclear particles which will be described later, the x in the inequations does not contain the amount of strontium in the nuclear particles.

From a viewpoint of shortening the wavelength, it is preferable that the amount of strontium is relatively large in the present embodiment.

In the present embodiment, it is preferable that the starting raw material (raw material mixed powder) contains SCASN phosphor nucleus particles having a median diameter equal to or more than 5 pm and equal to or less than 30 μm. That is, it is preferable that a part of the starting raw material is SCASN phosphor nucleus particles having an average particle diameter equal to or more than 5 μm and equal to or less than 30 μm. The average particle diameter is more preferably equal to or more than 10 μm and equal to or less than 20 pm.

In the present specification, the SCASN phosphor nuclear particles are also simply referred to as “nuclear particles”, “nucleus”, and the like.

Although the details are not clear, it is considered that, since the nuclear particles are used, the crystallization proceeds from the nuclear particles as a starting point in the subsequent firing step. Accordingly, it is considered that a method of crystal growth is different from a case where the firing step is performed without using the nuclear particles (for example, it is considered that, by using the nuclear, the composition of each particle is likely to be aligned, compared to a case where the nuclear is not used). Then, probably as a result, it is considered that it is easy to obtain a phosphor powder in which a peak wavelength of a fluorescence spectrum, in a case where the blue excitation light having a wavelength of 455 nm is emitted, is equal to or more than 600 nm and equal to or less than 610 nm and a full width at half maximum of the fluorescence spectrum is equal to or less than 73 nm. As an example, the nuclear particles can be a red phosphor represented by the same general formula as that of the red phosphor of the present embodiment described above. That is, regarding the nuclear particles, as an example, the peak wavelength of the fluorescence spectrum, in a case where the blue excitation light having a wavelength of 455 nm is emitted, is not necessarily equal to or more than 600 nm and equal to or less than 610 nm, and/or the full width at half maximum of the fluorescence spectrum is not equal to or less than 73 nm, but the composition is the same as or similar to that of the red phosphor of the present embodiment.

In a case where nuclear particles are used, the amount thereof is, for example, equal to or more than 1% by mass and equal to or less than 20% by mass and preferably equal to or more than 2% by mass and equal to or less than 15% by mass, in a total amount of the raw material mixed powder.

The nuclear particles can be obtained, for example, by undergoing a step substantially similar to that of the phosphor powder of the present embodiment. That is, in the step of producing the phosphor powder of the present embodiment, the nuclear particles can be obtained in almost the same manner, except that the nuclear particles are not added in the mixing step. The composition of the nuclear particles (general formula) is also preferably the same as that of the phosphor powder of the present embodiment.

In the mixing step, the raw material mixed powder can be obtained by using, for example, a method for dry-mixing the starting raw material, a method for wet-mixing in an inert solvent that does not substantially react with each starting raw material, and then removing the solvent, or the like. As a mixing device, for example, a small-sized mill mixer, a V-type mixer, a rocking mixer, a ball mill, a vibration mill, or the like can be used. After the mixing using the device, the aggregates can be removed by a sieve, as needed, to obtain a raw material mixed powder.

In order to suppress a deterioration of the starting raw material and unintentional mixing of oxygen, it is preferable that the mixing step is performed in a nitrogen atmosphere or in an environment where the water content (humidity) is as low as possible.

### Firing Step

In the firing step, the raw material mixed powder obtained in the mixing step is fired to obtain a fired product.

A firing temperature in the firing step is preferably equal to or higher than 1800° C. and equal to or lower than 2100° C. and more preferably equal to or higher than 1900° C. and equal to or lower than 2000° C. By setting the firing temperature to the lower limit value or higher, the grain growth of the phosphor particles proceeds more effectively. Accordingly, a light absorption rate, an internal quantum efficiency, and an external quantum efficiency can be further improved. By setting the firing temperature to the upper limit value or lower, the decomposition of the phosphor particles can be further suppressed. Accordingly, the light absorption rate, the internal quantum efficiency, and the external quantum efficiency can be further improved.

Other conditions such as a heating time, a heating rate, a heating holding time, and a pressure in the firing step are not particularly limited, and may be appropriately adjusted according to the raw materials used. Typically, the heating holding time is preferably equal to or longer than 3 hours and equal to or shorter than 30 hours, and the pressure is preferably equal to or more than 0.6 MPa and equal to or less than 10 MPa (gauge pressure) . From a viewpoint of controlling oxygen concentration, it is preferable that the firing step is performed in a nitrogen gas atmosphere. That is, it is preferable that the firing step is performed in a nitrogen gas atmosphere having a pressure equal to or more than 0.6 MPa and equal to or less than 10 MPa (gauge pressure).

At the time of firing, it is preferable to fill a container that does not easily react with the mixture during the firing, for example, a container made of a high melting metal, specifically a container having an inner wall made of tungsten, molybdenum, or tantalum with the mixture and heat the mixture. Accordingly, the generation of heterogeneous phase can be suppressed.

### Powdering Step

As an additional step, a powdering step may be performed. The fired product obtained through the firing step is normally a granular or lumpy sintered product. In a case where the fired product is lumpy and difficult to handle, the fired product can be once powderized to obtain a sintered powder by using treatments such as crushing, pulverization, and classification alone or in combination.

Specific examples of the treatment method include a method of crushing the sintered product to a predetermined particle size using a general crusher such as a ball mill, a vibration mill, or a jet mill. However, attention needs to be paid to excessive crush, because fine particles that easily scatter light maybe generated or crystal defects may be caused on a particle surface, resulting in a decrease in light emitting efficiency.

### Annealing Step

As an additional step, an annealing step may be performed. Specifically, after the firing step, there may be an annealing step of annealing the fired powder at a temperature lower than the firing temperature in the firing step to obtain an annealed powder. The annealing step is preferably performed in an inert gas such as a rare gas and a nitrogen gas, a reducing gas such as a hydrogen gas, a carbon monoxide gas, a hydrocarbon gas, and an ammonia gas, or a mixed gas thereof, or in a non-oxidizing atmosphere other than pure nitrogen such as a vacuum. The annealing step is particularly preferably performed in a hydrogen gas atmosphere or an argon atmosphere.

The annealing step may be performed under atmospheric pressure, pressurization, or decompression. A heat treatment temperature in the annealing step is preferably equal to or higher than 1300° C. and equal to or lower than 1400° C. The time of the annealing step is not particularly limited, and is preferably equal to or longer than 3 hours and equal to or shorter than 12 hours and more preferably equal to or longer than 5 hours and equal to or shorter than 10 hours.

By performing the annealing step, the light emitting efficiency of the phosphor particles can be sufficiently improved. In addition, the rearrangement of the elements removes strains and defects, so that transparency can also be improved.

In the annealing step, heterogeneous phases may occur. However, this can be sufficiently removed by a step which will be described later.

### Acid-Treatment Step

As an additional step, an acid treatment step maybe performed. In the acid treatment step, the annealed powder obtained in the annealing step is generally acid-treated. Accordingly, at least a part of impurities that do not contribute to light emission can be removed. In addition, it is assumed that the impurities that do not contribute to light emission are generated during the firing step and the annealing step.

As the acid, an aqueous solution containing one or more acids selected from hydrofluoric acid, sulfuric acid, phosphoric acid, hydrochloric acid, and nitric acid can be used. Particularly, hydrofluoric acid, nitric acid, and a mixed acid of hydrofluoric acid and nitric acid are preferable.

The acid treatment can be performed by dispersing the annealed powder in an aqueous solution containing the acid described above. A stirring time is, for example, equal to or longer than 10 minutes and equal to or shorter than 6 hours and preferably equal to or longer than 30 minutes and equal to or shorter than 3 hours. A temperature at the time of stirring can be, for example, equal to or higher than 40° C. and equal to or lower than 90° C. and preferably equal to or higher than 50° C. and equal to or lower than 70° C.

After the acid treatment step, the liquid in which the annealed powder is dispersed may be boiled.

After the acid treatment step, substances other than the phosphor powder may be separated by filtration, and if necessary, the substance attached to the phosphor particles may be washed with water. After washing with water, generally, the phosphor powder is dried by natural drying or drying in a dryer. The dried phosphor powder may be placed in a crucible and heated to modify the surface.

The phosphor powder of the present embodiment can be obtained by a series of steps described above.

### Composite

The composite includes, for example, the phosphor powder described above and a sealing material that seals the phosphor powder. In the composite, the phosphor powder described above is dispersed in the sealing material.

As the sealing material, a well-known material such as a resin, a glass, and ceramics can be used. Examples of the resin used for the sealing material include transparent resins such as a silicone resin, an epoxy resin, and a urethane resin.

Examples of a method for producing the composite include a producing method for adding the phosphor powder according to the present embodiment to a liquid resin, a glass, ceramics, or the like, uniformly mixing the mixture, and then curing or sintering the mixture by a heat treatment.

### Light-Emitting Device

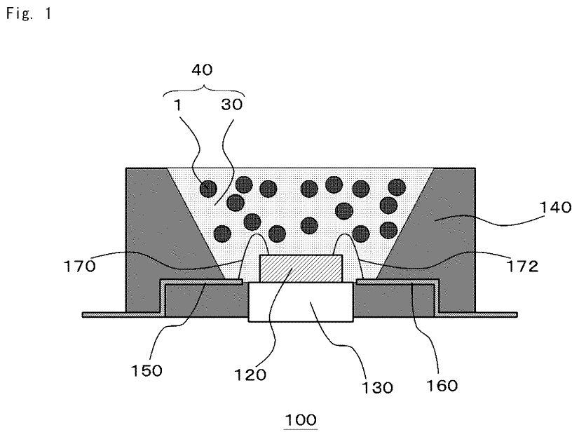

FIG. 1 is a schematic cross-sectional view showing an example of a structure of a light-emitting device. As shown in FIG. 1, a light-emitting device 100 includes a light-emitting element 120, a heat sink 130, a case 140, a first lead frame 150, a second lead frame 160, a bonding wire 170, a bonding wire 172, and a composite 40.

The light-emitting element 120 is mounted in a predetermined region on the upper surface of the heat sink 130. By mounting the light-emitting element 120 on the heat sink 130, the heat dissipation of the light-emitting element 120 can be enhanced. Further, a packaging substrate may be used instead of the heat sink 130.

The light-emitting element 120 is a semiconductor element that emits excitation light. As the light-emitting element 120, for example, an LED chip that generates light at a wavelength of equal to or more than 300 nm and equal to or less than 500 nm, corresponding to near-ultraviolet to blue light, can be used. One electrode (not shown in the drawings) arranged on the upper surface side of the light-emitting element 120 is connected to the surface of the first lead frame 150 through the bonding wire 170 such as a gold wire. In addition, the other electrode (not shown in the drawings) formed on the upper surface of the light-emitting element 120 is connected to the surface of the second lead frame 160 through the bonding wire 172 such as a gold wire.

In the case 140, a substantially funnel-shaped recess whose hole diameter gradually increases toward the upside from the bottom surface is formed. The light-emitting element 120 is provided on the bottom surface of the recess. The wall surface of the recess surrounding the light-emitting element 120 serves as a reflective plate.

The recess whose wall surface is formed by the case 140 is filled with the composite 40. The composite 40 is a wavelength conversion member that converts excitation light emitted from the light-emitting element 120 into light at a longer wavelength. The composite of the present embodiment is used as the composite 40, and phosphor powder 1 described above in a sealing material 30 such as a resin are dispersed. The light-emitting device 100 emits a mixed color of light of the light-emitting element 120 and light generated from the phosphor powder 1 that are excited by absorbing the light of the light-emitting element 120. In order to obtain white as a mixed color (to make the light-emitting device 100 a white LED), it is preferable that the composite 40 contains, for example, LuAG phosphor powder, in addition to the phosphor powder 1 (it is preferable that the LuAG phosphor powder is dispersed in the sealing material 30, in addition to the phosphor powder 1).

In the present embodiment, since the peak wavelength of the fluorescence spectrum of the phosphor powder 1 or the full width at half maximum are in certain numerical ranges, excellent white light can be easily obtained.

In addition, in FIG. 1, a surface mounting type light-emitting device is illustrated, but the light-emitting device is not limited to the surface mounting type device. The light-emitting device may be of a cannonball type, a chip-on-board (COB) type, or a chip-scale-package (CSP) type.

The embodiments of the present invention have been described above, but these are examples of the present invention and various configurations other than the examples can also be adopted. In addition, the present invention is not limited to the above-described embodiment, and modifications, improvements, and the like within the range in which the object of the present invention can be achieved are included in the present invention.

### EXAMPLES

The embodiment of the present invention will be described in detail based on examples and comparative examples. It is noted, just to be sure, that the present invention is not limited to only Examples.

### Production Example of Nuclear Particles

First, in a container, 61.38 g of α-type silicon nitride (Si₃N₄, manufactured by Ube Kosan Co., Ltd. , SN-E10 grade), 53.80 g of aluminum nitride (AlN, manufactured by Tokuyama Corporation, E grade), and 0.92 g of europium oxide (Eu₂O₃, manufactured by Shin-Etsu Chemical Co., Ltd.) were added and premixed.

Next, in a glove box held in a nitrogen atmosphere in which moisture is adjusted to equal to or less than 1 ppm by mass and an oxygen concentration is adjusted to equal to or less than 50 ppm, in the container, 2.98 g of calcium nitride (Ca3N₂, manufactured by Materion) and 120. 92 g of strontium nitride (Sr3N₂, purity of 2N, manufactured by High Purity Chemical Laboratory Co., Ltd.) were further added and dry-mixed. From the above, a raw material powder (mixed powder) was obtained.

In the glove box, a container with a lid made of tungsten was filled with 240 g of the above raw material powder. After closing the lid of this container with a lid, it was taken out from the glove box and placed in an electric furnace including a carbon heater. After that, a pressure in the electric furnace was sufficiently vacuum-exhausted until the pressure became equal to or less than 0.1 PaG.

While continuing the vacuum evacuation, a temperature inside the electric furnace was raised to 600° C. After reaching 600° C., nitrogen gas was introduced into the electric furnace, and the pressure in the electric furnace was adjusted to 0.9 MPaG. After that, in the atmosphere of nitrogen gas, the temperature inside the electric furnace was raised to 1950° C., and after the temperature reached 1950° C., the heat treatment was performed over 8 hours. After that, the heating was finished and the mixture was cooled to room temperature. After cooling to room temperature, a red mass was collected from the container. The collected lumps were crushed and sieved in a mortar to adjust the particle size.

By changing the method for adjusting the particle size, nuclear particles having an average particle diameter of 11 μm and nuclear particles having an average particle diameter of 18 μm were produced.

### Producing Phosphor Powder

### Example 1

In a container, 54.96 g of α-type silicon nitride (Si₃N₄, manufactured by Ube Kosan Co . Ltd., SN-E10 grade) 48.18 g of aluminum nitride (AlN, manufactured by Tokuyama Corporation, E grade), 0.41 g of europium oxide (Eu₂O₃, manufactured by Shin-Etsu Chemical Co., Ltd.), and 24.00 g of nuclear produced above having an average particle diameter of 18 μm were added and premixed.

Next, in a glove box held in a nitrogen atmosphere in which moisture is adjusted to equal to or less than 1 ppm by mass and an oxygen concentration is adjusted to equal to or less than 50 ppm, in the container, 1.34 g of calcium nitride (Ca₃N₂, manufactured by Materion) and 111.11 g of strontium nitride (Sr₃N₂, purity of 2N, manufactured by High Purity Chemical Laboratory Co., Ltd.) were further added and dry-mixed. Accordingly, a raw material powder (mixed powder) was obtained.

In the glove box, a container with a lid made of tungsten was filled with 240 g of the above raw material powder. After closing the lid of this container with a lid, it was taken out from the glove box and placed in an electric furnace including a carbon heater. After that, a pressure in the electric furnace was sufficiently vacuum-exhausted until the pressure became equal to or less than 0.1 PaG.

While continuing the vacuum evacuation, a temperature inside the electric furnace was raised to 600° C. After reaching 600° C., nitrogen gas was introduced into the electric furnace, and the pressure in the electric furnace was adjusted to 0.9 MPaG. After that, in the atmosphere of nitrogen gas, the temperature inside the electric furnace was raised to 1950° C., and after the temperature reached 1950° C., the heat treatment was performed over 8 hours. After that, the heating was finished and the mixture was cooled to room temperature. After cooling to room temperature, a red mass was collected from the container. The collected lumps were crushed and sieved, and the particle size was adjusted to obtain a red phosphor (fired powder).

A tungsten container was filled with the obtained fired powder, and the container was quickly transferred into an electric furnace including a carbon heater and sufficiently vacuum-exhausted until the pressure in the furnace became equal to or less than 0.1 PaG. Heating was started while the vacuum evacuation was continued, and when the temperature reached 600° C., argon gas was introduced into the furnace to adjust the pressure in the furnace atmosphere to atmosphere pressure. Even after the introduction of argon gas was started, the temperature was continuously raised to 1350° C. After the temperature reached 1350° C., the heat treatment was performed for 8 hours. After that, the heating was finished and the mixture was cooled to room temperature. After cooling to room temperature, the annealed powder was collected from the container. The collected powder was passed through a sieve to adjust the particle size. From the above, a red phosphor (annealed powder) was obtained.

The annealed powder was added to 2.0 M of hydrochloric acid at room temperature so that the slurry concentration was 25% by mass, and immersed for 1 hour. Accordingly, the acid treatment was performed. After the acid treatment, a hydrochloric acid slurry was boiled for 1 hour while stirring.

The slurry after the boiling treatment was cooled to room temperature and filtered, and an acid treatment liquid was separated from a synthetic powder. The synthetic powder after the acid treatment liquid separation was placed in a dryer having a temperature setting in a range of 100° C. to 120° C. for 12 hours.

An alumina crucible was filled with the dried powder after the acid treatment step, heated in the atmosphere at a rate of a temperature rise of 10° C./min, and heated at 400° C. for 3 hours. After the heat treatment, it was left to stand until it reached room temperature.

From the above, the phosphor powder of Example 1 was obtained.

Powder X ray diffraction using CuKa ray was performed on the obtained phosphor sample using an X-ray diffractometer (Ultima IV manufactured by Rigaku Corporation). In the obtained X-ray diffraction pattern, the same diffraction pattern as the CaAlSiN3 crystal was recognized, and it was confirmed that amain crystal phase had the same crystal structure as that of the CaAlSiN3 crystal.

### Example 2

A phosphor powder of Example 2 was obtained in the same manner as Example 1, except that, regarding the raw materials used, Si₃N₄=54.68 g, AlN=47.93 g, Eu₂O₃=0.41 g, Ca₃N₂=0.17 g, Sr₃N₂=112.81 g, and nucleus (average particle diameter of 18 μm)=24.00 g.

### Example 3

A phosphor powder of Example 3 was obtained in the same manner as Example 1, except that, regarding the raw materials used, Si₃N₄=54.94 g, AlN=48.18 g, Eu₂O₃=0.41 g, Ca₃N₂=1.34 g, Sr₃N₂=111.13 g, and nucleus (average particle diameter of 11 μm)=24.00 g.

### Comparative Example 1

A phosphor powder of Comparative Example 1 was obtained in the same manner as Example 1, except that, regarding the raw materials used, Si₃N₄=61.47 g, AlN=53.88 g, Eu₂O₃=0.46 g, Ca₃N₂=3.12 g, Sr₃N₂=121.07 g, and nucleus was not used.

### Comparative Example 2

A phosphor powder of Comparative Example 2 was obtained in the same manner as Example 1, except that, regarding the raw materials used, Si₃N₄=61.38 g, AlN=53.80 g, Eu₂O₃=0.92 g, Ca₃N₂=2.98 g, Sr₃N₂=120.92 g, and nucleus was not used.

### Comparative Example 3

A phosphor powder of Comparative Example 3 was obtained in the same manner as Example 1, except that, regarding the raw materials used, Si₃N₄=60.98 g, AlN=53.46 g, Eu₂O₃=0.92 g, Ca₃N₂=1.35 g, Sr₃N₂=123.29 g, and nucleus was not used.

### Comparative Example 4

A phosphor powder of Comparative Example 4 was obtained in the same manner as Example 1, except that, regarding the raw materials used, Si₃N₄=60.91 g, AlN=53.39 g, Eu₂O₃=0.92 g, Ca₃N₂=1.03 g, Sr₃N₂=123.75 g, and nucleus was not used.

### Measurement of Median Diameter

The measurement was performed by a laser diffraction scattering method based on JIS R1629: 1997, using Microtrac MT3300EX II (manufactured by MicrotracBEL Corporation). 0.5 g of a phosphor powder was put into 100 cc of ion exchange water, the mixture was subjected to a dispersion treatment with Ultrasonic Homogenizer US-150E (Nissei Corporation, chip size: φ20 mm, Amplitude: 100%, oscillation frequency: 19.5 KHz, amplitude of vibration: about 31 pm) for 3 minutes, and then the particle size was measured with MT3300EX II. The median diameter was determined from the obtained particle size distribution.

### Measurement of Fluorescence Spectrum

Fluorescence measurement was performed using a spectral fluorometer (F-7000, manufactured by Hitachi High-Technologies Corporation) corrected by Rhodamine B and a sub-standard light source. A solid sample holder attached to the photometer was used for the measurement, and a fluorescence spectrum at an excitation wavelength of 455 nm was obtained. From the obtained fluorescence spectrum, a peak wavelength of the fluorescence spectrum and a full width at half maximum of the fluorescence spectrum were obtained. In addition, a peak intensity (relative light emission peak intensity) was also obtained.

The peak intensity (relative light emission peak intensity) will be further described.

The relative light emission peak intensity is that a peak height of a light emission spectrum obtained by irradiating YAG:Ce (P46Y3 manufactured by Kasei Optonics Co., Ltd.) with monochromatic light at 455 nm was set to 100% and a peak height obtained by phosphor particles as a material to be measured was expressed as a relative peak intensity (%) . In short, the peak intensities in the examples and comparative examples are relative values with respect to the standard sample.

### Evaluation of Brightness

The brightness was evaluated, as described below, by calculating a value I obtained by integrating a product of the fluorescence spectrum intensity at each wavelength and the visual sensitivity in a region where a wavelength is 500 nm to 780 nm with the wavelength set as an integral variable. The value of the visual sensitivity was based on photopic spectral luminous efficiency in that light at a wavelength of 555 nm=1 is defined.

It can be said that the SCASN phosphor powder having a large value I can be preferably used for producing a high-brightness white LED.

I=∫₅₀₀⁷⁰⁰{(visual sensitivity)×(fluorescence spectrum intensity)} [Equation 1]

Table 1 collectively shows the charging ratio of the raw materials and various measurement/evaluation results.

In Table 1, “addition of large amount of Sr” means that Sr₃N₂ was used in an amount such that x in the general formula described above is 0.95≤x<1 at least in the charging ratio of raw materials.

In Table 1, the numerical values in columns of Si (mol ratio), Al (mol ratio), Eu (mol ratio), Ca (mol ratio), Sr (mol ratio), Eu+Sr+Ca, Sr/(Sr+Ca) do not include elements in the nuclear particles.

In Table 1, the numerical value in the column of Sr/(Sr+Ca) corresponds to a value of x/(1−y) in the general formula described above.

TABLE 1

| | | | | | | | | | | | Result | | | | |
|---|---|---|---|---|---|---|---|---|---|---|---|---|---|---|---|
| | Producing method | | | | | | | | | | | | Full | | |
| | | Addition | Charging ratio | | | | | | | | | Peak | width at | | |
| | | of large | Nuclear | Si | Al | Eu | Ca | Sr | Eu + | Sr/ | Median | wave- | half | Peak | Bright- |
| | Nuclear | amount | (% by | (mol | (mol | (mol | (mol | (mol | Sr + | (Sr + | diameter | length | maximum | inten- | ness |
| | addition | of Sr | mass) | ratio) | ratio) | ratio) | ratio) | ratio) | Ca | Ca) | (μm) | (nm) | (nm) | sity | I |
| Example 1 | Performed | Performed | 10 | 1 | 1 | 0.002 | 0.023 | 0.975 | 1 | 0.977 | 28.2 | 607.8 | 72.3 | 230.8 | 173.8523 |
| Example 2 | Performed | Performed | 10 | 1 | 1 | 0.002 | 0.003 | 0.995 | 1 | 0.997 | 26.9 | 604.0 | 71.5 | 223.6 | 172.0903 |
| Example 3 | Performed | Performed | 10 | 1 | 1 | 0.002 | 0.023 | 0.975 | 1 | 0.977 | 20.5 | 605.0 | 72.8 | 224.3 | 176.7784 |
| Comparative | — | — | — | 1 | 1 | 0.002 | 0.048 | 0.95 | 1 | 0.952 | 14.3 | 606.5 | 73.8 | 208.8 | 161.8511 |
| Example 1 | | | | | | | | | | | | | | | |
| Comparative | — | — | — | 1 | 1 | 0.004 | 0.046 | 0.95 | 1 | 0.954 | 13.9 | 610.5 | 73.5 | 233.3 | 162.1 |
| Example 2 | | | | | | | | | | | | | | | |
| Comparative | — | Performed | — | 1 | 1 | 0.004 | 0.021 | 0.975 | 1 | 0.979 | 19 | 611.5 | 72.3 | 237.4 | 166.7851 |
| Example 3 | | | | | | | | | | | | | | | |
| Comparative | — | Performed | — | 1 | 1 | 0.004 | 0.016 | 0.98 | 1 | 0.984 | 22.9 | 610.3 | 71.8 | 237.0 | 168.3959 |
| Example 4 | | | | | | | | | | | | | | | |

### Consideration of Examples and Comparative Examples

Although the peak wavelengths of the phosphor powders of Examples 1 to 3 are relatively short (equal to or more than 600 nm and equal to or less than 610 nm), the peak intensities of the phosphor powders were large values to the same extent as those in Comparative Examples 2 to 4 (peak wavelengths exceed 610 nm). It is surmised that this is probably because the phosphor powders of Examples 1 to 3 were designed so that the full width at half maximum was equal to or less than 73 nm.

In addition, compared to Examples 1 to 3 and Comparative Example 1 having the same peak wavelength, Comparative Example 1 had a small peak intensity probably because the full width at half maximum was more than 73 nm.

The brightness I of the phosphor powders of Examples 1 to 3 in which “the peak intensity is large even though the peak wavelength is relatively short” is equal to or more than 170, which is clearly larger value than those of Comparative Examples 1 to 4. From this, it is found that the phosphor powders of Examples 1 to 3 can be preferably used for producing a high-brightness white LED.

This application claims priority based on Japanese Patent Application No. 2020-061212 filed on Mar. 30, 2020, the disclosures of which are incorporated herein by reference in their entireties.

### REFERENCE SIGNS LIST

1: phosphor powder
30: sealing material
40: composite
100: light-emitting device
120: light-emitting element
130: heat sink
140: case
150: first lead frame
160: second lead frame
170: bonding wire
172: bonding wire

1. A phosphor powder consisting of a red phosphor represented by a general formula (Srₓ, Ca_{1-x-y}, Eu_{y})AlSi(N,O)₃ having the same crystal phase as that of CASN,
wherein relationships of x<1 and 1−x−y>0 are satisfied,
a peak wavelength of a fluorescence spectrum in a case where blue excitation light at a wavelength of 455 nm is emitted is equal to or more than 600 nm and equal to or less than 610 nm, and
a full width at half maximum of the fluorescence spectrum is equal to or less than 73 nm.

2. The phosphor powder according to claim 1,
wherein a relationship of y<0.01 is satisfied.

3. The phosphor powder according to claim 1,
wherein a molar ratio of Sr/(Sr+Ca) of the phosphor powder is equal to or more than 0.96 and equal to or less than 0.999.

4. The phosphor powder according to claim 1,
wherein the full width at half maximum of the fluorescence spectrum is equal to or more than 70 nm and equal to or less than 73 nm.

5. The phosphor powder according to claim 1,
wherein a median diameter is equal to or more than 1 μm and equal to or less than 40 μm.

6. A composite comprising:
the phosphor powder according to claim 1, and
a sealing material that seals the phosphor powder.

7. A light-emitting device comprising:
a light-emitting element that emits excitation light; and
the composite according to claim 6, that converts a wavelength of the excitation light.

8. A method for producing the phosphor powder according to claim 1, the method comprising:
a mixing step of mixing a starting raw material to form a raw material mixed powder; and
a firing step of firing the raw material mixed powder to obtain a fired product,
wherein the starting raw material contains SCASN phosphor nucleus particles having an average particle diameter equal to or more than 5 μm and equal to or less than 30 μm.

9. The method for producing the phosphor powder according to claim 8, the method further comprising:
an annealing step of annealing a fired powder at a temperature lower than a firing temperature in the firing step to obtain an annealed powder, after the firing step.

10. The method for producing the phosphor powder according to claim 9, the method further comprising:
an acid treatment step of performing acid treatment of the annealed powder obtained in the annealing step.
